(19) United States
(12) Patent Application Publication
(10) Pub. No.: US 2006/0146903 A1
(43) Pub. Date: Jul. 6, 2006

(54) Semiconductor light emitting device suppressing radiation of light other than light having desired wavelength

(75) Inventors: Ken Sasakura, Tokyo (JP); Keizo Kawaguchi, Tokyo (JP); Hanako Ono, Tokyo (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: Stanley Electric Co., Ltd., Tokyo (JP)

(21) Appl. No.: 11/266,655

(22) Filed: Nov. 3, 2005

(30) Foreign Application Priority Data
Jan. 5, 2005 (JP) 2005-000812

(51) Int. Cl. H01S 5/20; H01S 5/323

(52) U.S. Cl. 372/45.01

(57) ABSTRACT

A luminescence structure is formed on a substrate made of semiconductor or insulator. The luminescence structure has a lamination structure that an active layer made of semiconductor is sandwiched between a pair of clad layers made of semiconductor. The clad layer is made of the semiconductor having a band gap wider than an energy corresponding to a peak wavelength of an EL spectrum of the active layer. A carrier trap layer is disposed between the substrate and luminescence structure. A peak wavelength of an EL spectrum of the carrier trap layer is longer than a wavelength corresponding to a band gap of the substrate and the peak wavelength of the EL spectrum of the active layer. Electrodes are formed to inject current into the active layer.

### CROSS REFERENCE TO RELATED APPLICATION

This application is based on and claims priority of Japanese Patent Application No. 2005-000812 filed on Jan. 5, 2005, the entire contents of which are incorporated herein by reference.

### BACKGROUND OF THE INVENTION

A) Field of the Invention

The present invention relates to a semiconductor light emitting device, and more particularly to a semiconductor light emitting device capable of suppressing radiation of light other than light having a desired wavelength.

B) Description of the Related Art

An infrared light emitting device can be manufactured by using semiconductor material having a band gap in an infrared range. JP-A-2002-344013 discloses a light emitting device for infrared free-space optical communications, using an InGaAs strain quantum well layer as an active layer. This light emitting device has the InGaAs strain quantum well layer sandwiched by a pair of AlGaAs carrier confinement layers, and this lamination structure is sandwiched by a p-type AlGaAs clad layer and an n-type AlGaAs clad layer.

An electroluminescence spectrum of the light emitting device disclosed in JP-A-2002-344013 has a maximum intensity in an infrared wavelength range. Not all carriers injected into an active layer are recombined in the active layer, but some carriers overflow the active layer. These overflowing carriers are recombined in a layer other than the active layer and light having a wavelength different from a desired wavelength is emitted in some cases. In a light emitting device having a maximum intensity in an infrared wavelength range if carriers are recombined in a layer other than the active layer and light components in a visual wavelength range is radiated, the application field of this light emitting device is restricted.

### SUMMARY OF THE INVENTION

An object of this invention is to provide a semiconductor light emitting device capable of suppressing radiation of light having a wavelength different from a desired wavelength.

According to one aspect of the present invention, there is provided a semiconductor light emitting device comprising: a substrate made of semiconductor or insulator; a luminescence structure formed on the substrate and having an active layer made of semiconductor sandwiched between a pair of clad layers made of semiconductor, the clad layer being made of the semiconductor having a band gap wider than an energy corresponding to a peak wavelength of an EL spectrum of the active layer; a carrier trap layer disposed between the substrate and the luminescence structure, a peak wavelength of an EL spectrum of the carrier trap layer being longer than a wavelength corresponding to a band gap of the substrate and the peak wavelength of the EL spectrum of the active layer; and electrodes for injecting current into the active layer.

Carriers overflowing the active layer are trapped by the carrier trap layer and recombined in the carrier trap layer. By controlling the wavelength of light emitted through recombination of carriers in the carrier trap layer, it is possible to suppress radiation of light having a wavelength different from a desired wavelength.

### BRIEF DESCRIPTION OF THE DRAWINGS

FIG. 1A is a schematic cross sectional view of a semiconductor light emitting device according to a first embodiment, and FIG. 1B is a schematic cross sectional view of a carrier trap layer of the semiconductor light emitting device.

FIG. 2 is a schematic cross sectional view of a semiconductor light emitting device proposed previously by the present inventors.

FIG. 3 is a schematic cross sectional view of a semiconductor light emitting device according to a second embodiment.

FIG. 4 is a graph showing an EL spectrum of the semiconductor light emitting device of the second embodiment, as compared to an EL spectrum of the semiconductor light emitting device proposed previously by the present inventors.

FIG. 5A is a cross sectional view showing a lamination structure of a carrier trap layer of a semiconductor light emitting device according to a third embodiment and FIG. 5B is a graph showing an EL spectrum.

### DESCRIPTION OF THE PREFERRED EMBODIMENTS

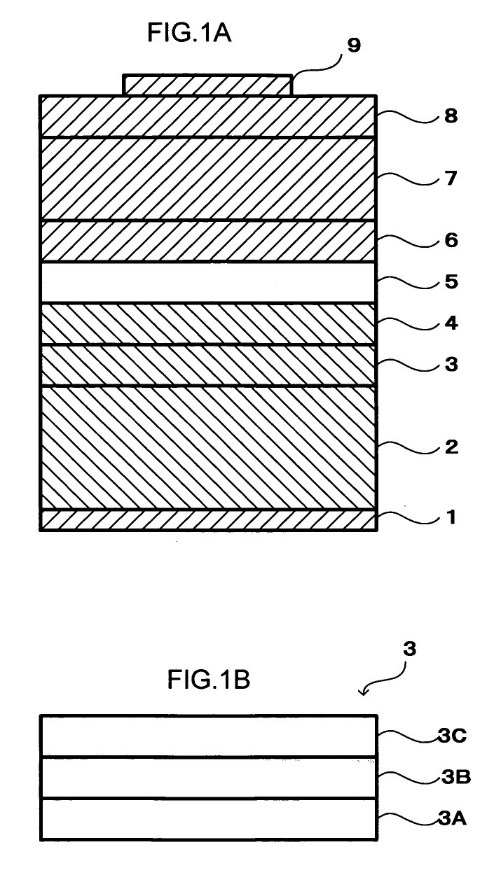

FIG. 1A is a schematic cross sectional view of a semiconductor light emitting device according to the first embodiment. On a principal surface of a semiconductor substrate 2 made of p-type AlGaAs, a carrier trap layer 3, a lower clad layer 4, an active layer 5, an upper clad layer 6, a current spreading layer 7, and a contact layer 8 are stacked in this order from the bottom.

FIG. 1B shows a lamination structure of the carrier trap layer 3. The carrier trap layer 3 has a three-layer structure of a lower barrier layer 3A, a quantum well layer 3B and an upper barrier layer 3C, stacked in this order from the bottom. The quantum well layer 3B is made of Zn— or Mg-doped p-type InGaAs, has an In composition ratio of 0 or larger and 0.25 or smaller, and has a thickness of 2 to 20 nm. The barrier layers 3A and 3C are made of Zn— or Mg-doped p-type AlGaAs, have an Al composition ratio of 0 or larger and equal to or smaller than an Al composition ratio of the substrate, and each of them has a thickness of 10 to 200 nm. The lower clad layer 4 is made of Zn— or Mg-doped p-type AlGaAs and has a thickness of 1 to 3 μm. A composition ratio of Al of the lower clad layer 4 is 0.3 to 0.4. An impurity concentration of the carrier trap layer 3 and lower clad layer 4 is 1×10¹⁶ cm⁻³ to 1×10¹⁸ cm⁻³.

The active layer 5 is made of p-type GaAs and has a thickness of 50 to 500 nm. An impurity concentration of the active layer 5 is 1×10¹⁷ cm⁻³ to 5×10¹⁸ cm⁻³.

The upper clad layer 6 is made of Si— or Se-doped n-type AlGaAs and has a thickness of 1 to 3 μm. A composition ratio of Al of the upper clad layer 6 is 0.3 to 0.4 and an impurity concentration is 1×10¹⁶ cm⁻³ to 1×10¹⁸ cm⁻³. The current spreading layer 7 is made of n-type AlGaAs and has a thickness of about 4.5 μm. An impurity concentration of the current spreading layer 7 is about 1×10¹⁸ cm⁻³. The contact layer 8 is made of n-type GaAs and has a thickness of about 50 nm. An impurity concentration of the contact layer 8 is about 2×10¹⁸ cm⁻³.

These layers can be formed, for example, by Metal Organic Chemical Vapor Deposition (MOCVD).

A lower electrode 1 made of AuZn alloy is formed on the bottom of the semiconductor substrate 2. An upper electrode 9 made of AuGe alloy is formed on the upper surface of the contact layer 8. These electrodes are formed, for example, by vacuum evaporation. By injecting current into the active layer 5 from the upper and lower electrodes 9 and 1, luminescence occurs in the active layer 5. The upper electrode 9 is patterned so that light radiated from the active layer 5 can be output to an external.

As described earlier, the clad layers 4 and 6 have a band gap wider than an energy corresponding to a wavelength (peak wavelength) at which an electroluminescence (EL) spectrum of the active layer 5 has the maximum value. Therefore, the clad layers 4 and 6 function as a potential barrier for confining carriers in the active layer 5.

In the carrier trap layer constituted of the quantum well layer 3B and barrier layers 3A and 3C, an energy corresponding to a luminescence wavelength between a ground quantum level in the conduction band and a ground quantum level in the valence band is narrower than the band gap of the semiconductor substrate 2. Most of electrons injected into the active layer 5 via the upper clad layer 6 are recombined with holes in the active layer 5. Luminescence occurs during recombination. Some electrons are not recombined in the active layer 5, flow over the potential barrier of the lower clad layer 4 and reach the carrier trap layer 3.

Since the band gap of the quantum well layer 3B constituting the carrier trap layer 3 is narrower than that of the semiconductor substrate 2, electrons are temporarily trapped in the carrier trap layer 3 and recombined with holes in the carrier trap layer 3. Luminescence occurs during recombination. By controlling the wavelength of light generated in the carrier trap layer by recombination, it is possible to suppress radiation of light having a wavelength different from a desired wavelength.

For the purposes of comparison, description will be made on the light emitting device without the carrier trap layer 3. In this case, electrons flowed over the potential barrier of the lower clad layer 4 are recombined in the substrate 2. The wavelength of light radiated by recombination is on a shorter wavelength side than the electroluminescence main peak of the active layer, because the band gap of the substrate 2 is wider than that of the active layer 5. Since luminescence on the shorter wavelength side is in a visible range, light radiated from the light emitting device is colored.

In the semiconductor light emitting device of the first embodiment, electrons not recombined in the active layer and overflowing can be recombined in the carrier trap layer before the electrons reach the substrate. By controlling the luminescence wavelength in the carrier trap layer, it is possible to suppress radiation of light having a wavelength different from a desired wavelength.

Next, prior to describing the second embodiment, description will be made on the semiconductor light emitting device proposed previously by the present inventors.

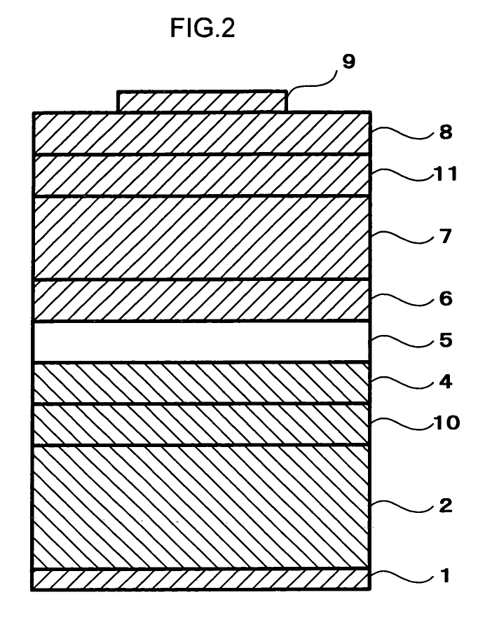

FIG. 2 is a schematic cross sectional view of a semiconductor light emitting device proposed previously by the present inventors. On a principal surface of a semiconductor substrate 2, a lower optical absorption layer 10, a lower clad layer 4, an active layer 5, an upper clad layer 6, a current spreading layer 7, an upper optical absorption layer 11 and a contact layer 8 are laminated in this order from the bottom.

The lower optical absorption layer 10 is made of p-type AlGaAs and has a thickness of 1 to 3 μm. An impurity concentration of the lower optical absorption layer 10 is about 1×10¹⁸ cm⁻³. The lower clad layer 4 is made of p-type AlGaAs and has a thickness of 0.1 μm or thicker and thinner than 5 μm. A composition ratio of Al of the lower clad layer 4 is 0.3 to 0.4 and an impurity concentration is 1×10¹⁶ cm⁻³ to 1×10¹⁸ cm⁻³. The active layer 5 is made of p-type GaAs and has a thickness of 50 to 500 nm. An impurity concentration of the active layer 5 is 1×10¹⁷ cm⁻³ to 5×10¹⁸ cm⁻³.

The upper clad layer 6 is made of n-type AlGaAs and has a thickness of 1 to 3 μm. A composition ratio of Al of the upper clad layer 6 is 0.3 to 0.4 and an impurity concentration is 1×10¹⁶ cm⁻³ to 1×10¹⁸ cm⁻³. The current spreading layer 7 is made of n-type AlGaAs and has a thickness of about 4.5 μm. An impurity concentration of the current spreading layer 7 is about 1×10¹⁸ cm⁻³.

The upper optical absorption layer 11 is made of n-type AlGaAs and has a thickness of 0.1 μm or thicker and thinner than 5 μm. An impurity concentration of the upper optical absorption layer 11 is about 1×10¹⁸ cm⁻³. The contact layer 8 is made of n-type GaAs and has a thickness of about 50 nm. An impurity concentration of the contact layer 8 is about 2×10¹⁸ cm⁻³.

A lower electrode 1 made of AuZn alloy is formed on the bottom of the substrate 2. An upper electrode 9 made of AuGe alloy is formed on the upper surface of the contact layer 8.

The substrate 2 is made of material which is transparent in a luminescence wavelength range of the active layer 5, such as p-type AlGaAs and p-type GaP. Namely, the substrate 2 has a band gap wider than the energy corresponding to a peak wavelength of an EL spectrum of the active layer 5. A substrate made of insulator such as sapphire may be used as the substrate 2. In this case, since the lower electrode 1 cannot be formed on the bottom of the substrate 2, a semiconductor layer of p-type AlGaAs or the like is formed between the lower optical absorption layer 10 and substrate 2, and the lower electrode is formed on this semiconductor layer.

Light generated in the active layer 5 is radiated to an external from both the contact layer 8 side and substrate 2 side. Although the peak wavelength of the EL spectrum of the active layer 5 is in the infrared range, a skirt on the shorter wavelength side extends to the visual range. Since the upper optical absorption layer 11 and lower optical absorption layer 10 absorb components in the visual range, it is possible to prevent externally radiated light from being colored.

It is preferable to select material of the optical absorption layers 10 and 11 in such a manner that the peak wavelength of the EL spectrum of the optical absorption layers 10 and 11 is shorter than the peak wavelength of the EL spectrum of the active layer 5, in order to efficiently radiate light in the infrared range to the external. It is also preferable to select material of the optical absorption layers 10 and 11 in such a manner that the peak wavelength of the EL spectrum of the optical absorption layers 10 and 11 is longer than the wavelength corresponding to the band gap of the substrate 2. It is also preferable to select material of the optical absorption layers 10 and 11 in such a manner that the peak wavelength of the EL spectrum of the optical absorption layers 10 and 11 is longer than the wavelength at the position where the intensity of the EL spectrum of the active layer 5 lowers to 10% of the peak intensity, on the side of the wavelength shorter than the peak wavelength of the EL spectrum of the active layer 5.

In the device shown in FIG. 2, as electrons overflow the active layer 5, the electrons are trapped by the lower optical absorption layer 10 and recombined in this layer. Light generated by recombination forms a shoulder on a slanted portion of the EL spectrum on the shorter wavelength side. The second embodiment to be described below can prevent the shoulder from being formed.

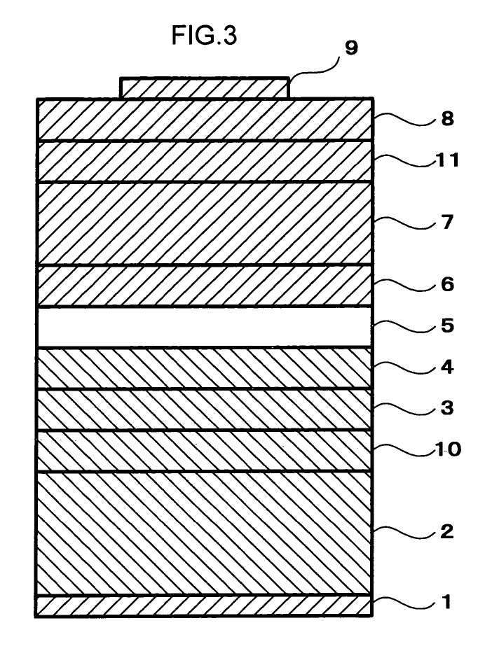

FIG. 3 is a schematic cross sectional view of a semiconductor light emitting device according to the second embodiment. A carrier trap layer 3 is inserted between the lower clad layer 4 and lower optical absorption layers 10 of the semiconductor light emitting device shown in FIG. 2. The other structures are the same as those of the semiconductor light emitting device shown in FIG. 2. The carrier trap layer 3 has the quantum well structure shown in FIG. 1B. The peak wavelength of the EL spectrum of the carrier trap layer 3, i.e., a peak luminescence wavelength by recombination between a ground quantum level in the conduction band and a ground quantum level in the valence band, is longer than any of the peak wavelength of the EL spectrum of the active layer 5, the peak wavelength of the EL spectrum of the lower optical absorption layer 10 and the peak wavelength of the EL spectrum of the substrate 2. Therefore, light generated by recombination of electrons trapped in the carrier trap layer 3 is radiated to the external from both of the contact layer 8 side and substrate 2 side. Since the light generated in the carrier trap layer 3 is infrared light, it is possible to prevent externally radiated light from being colored.

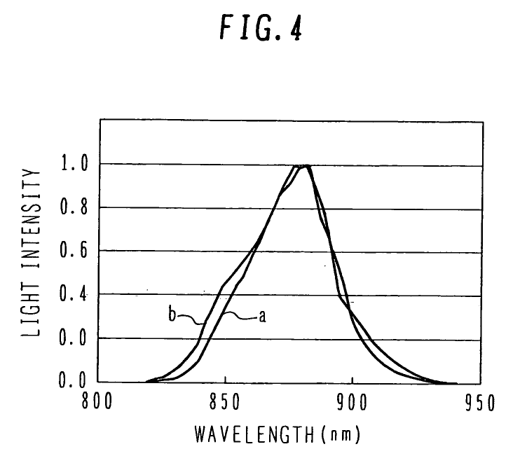

FIG. 4 shows the EL spectrum of the semiconductor light emitting device of the second embodiment shown in FIG. 3. The abscissa represents a wavelength in the unit of “nm” and the ordinate represents a light intensity in a relative value with the maximum intensity being set to “1”. The EL spectrum of the semiconductor light emitting device of the second embodiment is shown by a heavy line a in FIG. 4. For the purposes of comparison, an EL spectrum of a semiconductor light emitting device not disposing the carrier trap layer 3 shown in FIG. 3 is shown by a fine line b. It can be understood that the light intensity in the skirt portion on the side of a wavelength shorter than a wavelength of about 860 nm is stronger than that of the second embodiment, when the carrier trap layer 3 of FIG. 3 is not disposed. A strong light intensity in the shorter wavelength range may be ascribed to that electrons overflowing the active layer 5 reach the lower optical absorption layer 10 and radiative recombination occurs in this layer. It can be understood that luminescence in the lower optical absorption layer 10 can be prevented by disposing the carrier trap layer 3.

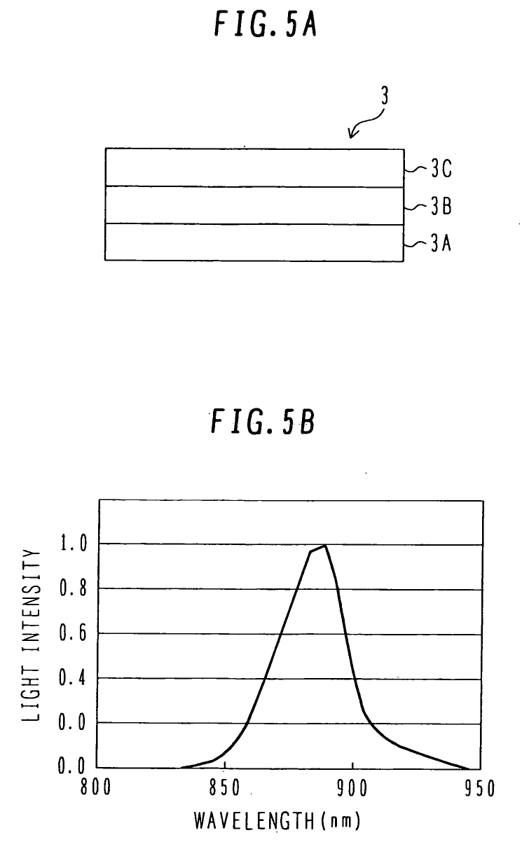

With reference to FIG. 5A and 5B, description will be made on a semiconductor light emitting device of the third embodiment. The lamination structure of the semiconductor light emitting device is the same as that of the semiconductor light emitting device of the second embodiment shown in FIG. 3.

FIG. 5A is a schematic cross sectional view of the carrier trap layer 3. A p-type InGaAs quantum well layer 3B is sandwiched between p-type GaAs barrier layers 3A and 3B. Impurities doped in these layers are Zn. A thickness of the quantum well layer 3B is 2 to 20 nm and a thickness of each of the barrier layers 3A and 3C is 10 to 200 nm. By adjusting the thickness and In composition ratio of the quantum well layer 3B, it is possible to change the peak wavelength of the EL spectrum of the carrier trap layer 3. In the third embodiment, it is adjusted in such a manner that the peak wavelength of the EL spectrum of the carrier trap layer 3 is set to the wavelength in the skirt portion on the longer wavelength side of the EL spectrum of the active layer 5.

FIG. 5B shows the EL spectrum of the semiconductor light emitting device of the third embodiment. It can be seen that the skirt portion on the side of a longer wavelength than a wavelength of 900 nm swells more than that on the shorter wavelength side. The reason for this is luminescence by recombination in the carrier trap layer 3. In this manner, infrared light can be radiated to the external by adjusting the peak wavelength of the EL spectrum of the carrier trap layer 3.

In order to prevent coloring of externally radiated light, it is preferable to set the peak wavelength of the EL spectrum of the carrier trap layer 3 longer than the peak wavelength of the EL spectrum of the active layer 5. It can be considered that a spectrum of light generated in the active layer 5 and a spectrum of light generated in the carrier trap layer 3 are combined to form one peak, if the peak wavelength of the EL spectrum of the carrier trap layer 3 is made shorter than the wavelength at which the light intensity becomes 10% of the maximum light intensity, on the side of a longer wavelength than the peak wavelength of the EL spectrum of the active layer 5. This provides the same effects as improvements on a luminescence efficiency of the active layer 5.

In the above-described embodiments, although the description is directed to the semiconductor light emitting device for radiating light mainly in the infrared range, the technical concept of the embodiments is also applicable to semiconductor light emitting devices for radiating light in other wavelength ranges. In the above-described embodiments, although a single semiconductor layer structure is used as the active layer, the active layer may have a quantum well structure or a multiple quantum well structure. Further, in the above-described embodiments, although the carrier trap layer has the quantum well structure, it may have a single semiconductor layer structure.

The present invention has been described in connection with the preferred embodiments. The invention is not limited only to the above embodiments. It will be apparent to those skilled in the art that other various modifications, improvements, combinations, and the like can be made.

What we claim are:

1. A semiconductor light emitting device comprising:
a substrate made of semiconductor or insulator;
a luminescence structure formed on the substrate and having an active layer made of semiconductor sandwiched between a pair of clad layers made of semiconductor, the clad layer being made of the semiconductor having a band gap wider than an energy corresponding to a peak wavelength of an EL spectrum of the active layer;
a carrier trap layer disposed between the substrate and the luminescence structure, a peak wavelength of an EL spectrum of the carrier trap layer being longer than a wavelength corresponding to a band gap of the substrate and the peak wavelength of the EL spectrum of the active layer; and
electrodes for injecting current into the active layer.

2. The semiconductor light emitting device according to claim 1, wherein:
the band gap of the substrate is larger than the energy corresponding to the peak wavelength of the EL spectrum of the active layer; and
the semiconductor light emitting device further comprises an optical absorption layer disposed between the substrate and the carrier trap layer, a peak wavelength of an EL spectrum of the optical absorption layer being longer than the wavelength corresponding to the band gap of the substrate and shorter than the peak wavelength of the EL spectrum of the active layer.

3. The semiconductor light emitting device according to claim 2, wherein the peak wavelength of the EL spectrum of the optical absorption layer is longer than a wavelength at which an intensity is 10% of a peak intensity of the EL spectrum of the active layer, on a side of a shorter wavelength than the peak wavelength of the EL spectrum of the active layer.

4. The semiconductor light emitting device according to claim 1, wherein the peak wavelength of the EL spectrum of the carrier trap layer is shorter than a wavelength at which an intensity is 10% of a peak intensity of the EL spectrum of the active layer, on a side of a longer wavelength than the peak wavelength of the EL spectrum of the active layer.

5. The semiconductor light emitting device according to claim 1, wherein the carrier trap layer has a quantum well structure.
